(19) United States
(12) Patent Application Publication
(10) Pub. No.: US 2025/0308850 A1
(43) Pub. Date: Oct. 2, 2025

(54) GROUNDING PLATE FOR STRESS TUNING HIGH DENSITY AND MODULUS FILMS

(71) Applicant: Applied Materials, Inc., Santa Clara, CA (US)

(72) Inventors: Soonil LEE, Santa Clara, CA (US); Abhijit Basu MALLICK, Fremont, CA (US); Rajaram NARAYANAN, Santa Clara, CA (US); Prapti PARAB, Sunnyvale, CA (US); Toan Q. TRAN, San Jose, CA (US); Qinye LIU, San Jose, CA (US); Diwakar KEDLAYA, San Jose, CA (US); Pramit MANNA, Santa Clara, CA (US); Karthik JANAKIRAMAN, San Jose, CA (US)

(21) Appl. No.: 18/620,411

(22) Filed: Mar. 28, 2024

(51) Int. Cl. H01J 37/32

(52) U.S. Cl. CPC H01J 37/32174; H01J 37/32091; H01J 37/321; H01J 37/32568; H01J 37/32715

(57) ABSTRACT

A process chamber for forming film high density and modulus films is provided. The process chamber includes a lid assembly, an inductively coupled plasma source disposed on the lid assembly, and a chamber body coupled to the lid assembly, wherein the lid assembly comprises a non-conductive material for providing a dielectric break between the inductively coupled plasma source and the chamber body. The process chamber also includes a substrate support comprising a powered electrode and a grounding plate coupled to an electrical ground and disposed between the lid assembly and the chamber body. The grounding plate is configured to operate as part of a grounded electrode for generating a plasma in the processing volume between the powered electrode and the grounded electrode.

### BACKGROUND

### Field

Embodiments of the present disclosure generally relate to apparatuses for semiconductor processing. More specifically, embodiments described herein relate to a grounding plate for use in a process chamber to facilitate tuning and reduction compressive stress in deposited films without sacrificing film density and modulus.

### Description of the Related Art

Integrated circuits have evolved into complex devices that can include millions of transistors, capacitors and resistors on a single chip. The evolution of chip designs continually involves faster circuitry and greater circuit density. The demands for faster circuits with greater circuit densities impose corresponding demands on the materials used to fabricate such integrated circuits. In particular, as the dimensions of integrated circuit components are reduced to the sub-micron scale, there is a trend to use low resistivity conductive materials as well as low dielectric constant insulating materials to obtain suitable electrical performance from such components.

As the pattern dimensions are reduced, the thickness of the energy sensitive resist is correspondingly reduced in order to control pattern resolution. Such thin resist layers can be insufficient to mask underlying material layers during the pattern transfer process due to attack by the chemical etchant. An intermediate layer (e.g., silicon oxynitride, silicon carbine or carbon film), called a hardmask, is often used between the energy sensitive resist layer and the underlying material layers to facilitate pattern transfer because of greater resistance to the chemical etchant. Hardmask materials having both high etch selectivity and high deposition rates are often utilized. As critical dimensions (CD) decrease, current hardmask materials lack the desired etch selectivity relative to underlying materials (e.g., oxides and nitrides) and are often difficult to deposit.

To achieve greater etch selectivity, films with improved density and, more importantly, the Young's modulus of the film have been made. However, one of the main challenges in achieving greater etch selectivity and improved Young's modulus is the high compressive stress of such a film making it unsuitable for applications owing to the resultant high wafer bow. Low film stress is therefore also desirable for preventing line wiggling and improving localize critical dimension uniformity. Wiggling refers to movement of film in a wave pattern. Conventional attempts to reduce compressive stress have inadvertently led to corresponding reductions in a modulus of the films, which can also mechanically deform the films and can degrade device performance. Such drawbacks can become even more pronounced as chip designs continually involve faster circuitry and greater circuit density.

Therefore, there is a need for improved systems and apparatus for forming thin films with high density and modulus and reduced compressive film stress to maintain high etch selectivity as well as to facilitate reduced wiggling, reduced deformation, and enhanced device performance.

### SUMMARY

Embodiments described herein generally relate to apparatus for forming films on a substrate. More specifically, embodiments described herein relate to a process chamber for forming films with high density and modulus and reduced compressive stress.

In one embodiment, a process chamber is provided. The process chamber includes a chamber body having a processing volume and a substrate support comprising a powered electrode in which the substrate support is disposed in the chamber body and partially defines the processing volume. The process chamber also includes a gas distributor disposed above the chamber body and facing the substrate support, wherein the gas distributor is electrically insulated from the chamber body, and a RF power source configured to apply a RF power to the powered electrode to generate and maintain a plasma in the processing volume between the powered electrode and a grounded electrode. A grounding plate is also disposed between the chamber body and the gas distributor and partially defining the processing volume, wherein the grounding plate is coupled to an electrical ground, comprises a plurality of passages extending therethrough, and is configured to operate as at least part of the grounded electrode for generating and maintaining the plasma in the processing volume

In another embodiment, a process chamber is provided. The process chamber includes a lid assembly, an inductively coupled plasma source disposed on the lid assembly, and a chamber body coupled to the lid assembly, wherein the lid assembly and the chamber body defines a chamber volume, and the lid assembly comprises a non-conductive material for providing a dielectric break between the inductively coupled plasma source and the chamber body. The process chamber also includes a substrate support comprising a powered electrode in which the substrate support is disposed in the chamber volume and partially defines a processing volume in the chamber volume, and a grounding plate coupled to an electrical ground and disposed between the lid assembly and the chamber body. The grounding plate is configured to operate as part of a grounded electrode for generating a plasma in the processing volume between the powered electrode and the grounded electrode, and a grounded surface area of the grounded electrode comprises a surface area of the grounding plate and an interior surface area of the chamber body.

In a further embodiment, a process chamber is provided. The process chamber includes a lid assembly, an inductively coupled plasma source disposed on the lid assembly, and a chamber body coupled to the lid assembly. The lid assembly and the chamber body defines a chamber volume and the lid assembly is electrically insulated from the chamber body. The process chamber also includes a substrate support comprising a powered electrode, the substrate support disposed in the chamber volume and partially defining a processing volume in the chamber volume, a grounding plate coupled to an electrical ground and disposed between the lid assembly and the chamber body. The grounding plate includes a plate body configured to be coupled with the chamber body and partially defining the processing volume, a plurality of passages extending through the plate body, and a grounding surface facing the processing volume and the substrate support when the plate body is coupled to the chamber body. The plate body is configured to operate as part of a grounded electrode for generating a capacitvely coupled plasma in the processing volume between the powered electrode and the grounded electrode. A grounded surface area of the grounded electrode includes a surface area of the plate body and an interior surface area of the chamber body at least partially defining the processing volume when the plate body is coupled to the chamber body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic side cross sectional view of an illustrative process chamber, according to certain embodiments;

FIG. 2 is a schematic side cross sectional view of another illustrative process chamber, according to certain embodiments;

FIG. 3 depicts a comparative graphical representation of sheath voltage of deposited films, according to certain embodiments of the present disclosure; and

FIG. 4 depicts a comparative graphical representation of stress results of deposited films, according to certain embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to apparatus and systems for forming film high density and modulus films. The present disclosure provides for tuning and reducing compressive stress of the deposited films. Aspects of the present disclosure may be used with substrate processing systems, such as plasma-enhanced chemical vapor deposition (PECVD) system and chamber. In some embodiments, PECVD can be used to form a “diamond-like” carbon (DLC) film. Such films have high density and modulus and when subsequently used as a hardmask during etching operations, provide for high etch selectivity. However, such films also contain high sp³ content that cause high compressive stress on the film. The high compressive stress can make such films unsuitable for use due to the resultant tendency for high substrate (e.g., wafer) bowing. In contrast, films deposited with less stress facilitate improved planarity (e.g., less bowing) of substrates upon which the film is formed. Reduced bowing of substrates can also result in improved precision of downstream patterning operations.

In some embodiments, radio frequency (RF) excited capacitively coupled plasma (CCP) utilized in a PECVD process chamber can be used to form high density and modulus films on a substrate. In some embodiments, the CCP is generated by applying an RF power discharge to a powered electrode opposite a grounded electrode/surface. In PECVD processes that require a higher RF input power (e.g., over 550 W), once the plasma has been created, a high self-induced negative DC bias is naturally established at the powered electrode in the process chamber. In a confined plasma, the electrons tend to leave the plasma readily due to their low mass and high mobility. This effect results in the formation of sheaths separating the quasi-neutral plasma from confining surfaces accompanied by a potential difference to reach an equilibrium where the ion and electron losses to the confining surfaces balance each other. Hence, additional energy needs to be delivered for ionization processes to sustain the plasma. As applied in a PECVD process chamber, since the plasma is at a higher potential than the self-induced negative DC bias of the powered electrode, the electrical potential difference between the plasma and the powered electrode forms an ion sheath that sits between the plasma and the powered electrode with a sheath voltage, V_{DC, then} being established at the powered electrode. In some embodiments, the powered electrode includes a substrate support of the process chamber, and when the substrate support is holding a substrate for a process, the ion sheath sits between the plasma and the substrate. The ion sheath thickness between the plasma and the substrate/powered electrode is inversely proportional to the plasma density and the process operating pressure.

The plasma assumes a positive potential to produce a potential of equivalent magnitude at the ground to reflect the larger ion sheath potential caused by the positive DC bias voltage being applied to the powered electrode. The voltage drop across the ion sheath causes positive ions from the plasma to accelerate toward the powered electrode. With no collisions, the accelerating ions across the ion sheath gain the sheath voltage in terms of ion energy. The ions acquire an average ion energy (eV) equivalent to the sum of the self-induced DC bias and the plasma potential. If the ions arrive at the substrate/electrode with high energies, high energy ion bombardment by the ions can occur. Such energetic ion bombardment enables materials to be selectively removed/etched using such plasma sources. On the other hand, if the ions arrive at the substrate/electrode with low energies, the ions may instead be utilized in a deposition process, such as being deposited on the substrate to form a film.

Accordingly, the deposition of or etch by the accelerating ions is dependent on the acquired ion energy. As mentioned above, the average ion energy acquired by the ions accelerating across the ion sheath is the sum of the self-induced DC bias and the plasma potential. Factors that can influence the ion energy include chamber pressure, the ratio between the surface area of the ground in the process chamber and the RF electrode, and the forward RF power provided. The dependence of ion energy on chamber pressure is related to the mean-free-path of the ions, which define the average distance the particles travel before encountering a collision. A larger mean-free-path will therefore result in a higher DC self-bias voltage and its inverse proportionality to pressure is defined by the kinetic theory of gas. For example, at high pressures, the ion sheaths are generally highly collisional and most of the ions therefore have a low energy upon arrival at the electrode/substrate surface. At low pressures, the ions have a long free path and can acquire high energies while traversing the ion sheath. Under such conditions, assuming that the ions fly through the sheaths in a fraction of the RF period, their energy is determined by the instantaneous sheath voltage. In the opposite case, i.e. when the ion transit time is much longer than the RF period, the ion energy is largely determined by the time-averaged sheath voltage.

Since the plasma potential is proportional to and depends strongly on the ratio between the ground and the powered electrode, increasing the ratio in turn causes increases in the plasma potential. For example, a large ratio due to a large disparity between the larger surface area of the ground (e.g., chamber walls) and the smaller powered RF electrode, can cause a stronger negative self-bias to be established at the powered RF electrode in the absence of DC grounding. When the electrical potential difference between the powered electrode and the plasma is increased, the sheath voltage at the powered electrode also increases, which results in increases in ion energy acquired by the ions accelerating in the ion sheath and an increase in the collision force of the ions against the substrate.

The present disclosure contemplates that by increasing plasma potential during deposition processing, the compressive stress of the formed film can be reduced without much impact to the high density and modulus of the formed film. In some embodiments, techniques of the present disclosure provide for increasing the surface area of ground inside the process chamber and hence the ratio between the ground and the smaller powered electrode to provide and maintain a higher plasma potential during film deposition. In some embodiments, the surface area of ground inside the process chamber is increased by incorporating a grounding plate to partially define the processing volume of the process chamber and increase the surface area of ground inside the process chamber with the surface area of the grounding plate. Without being bound theory, in some embodiments, increasing the plasma potential when forming the DLC film can provide for more and stronger ion bombardment that can break localized sp³ bonding in the formed film during deposition, as well as locally heat up the film.

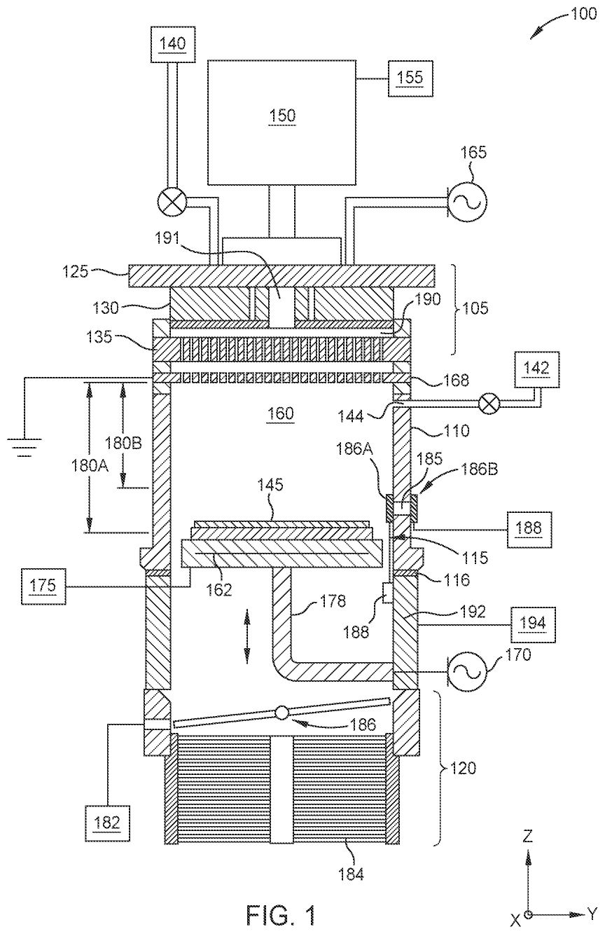

FIG. 1 is a schematic side cross sectional view of an illustrative process chamber 100 suitable for conducting a deposition process, according to certain embodiments of the present disclosure. Although FIG. 1 depicts one chamber suitable for conducting the deposition process described herein, other chambers are also contemplated. In one embodiment, which can be combined with other embodiments described herein, the process chamber 100 is configured to deposit advanced patterning films onto a substrate, such as hardmask films, for example amorphous carbon hardmask films.

The process chamber 100 includes a lid assembly 105, an optional spacer 110 disposed on a chamber body 192, a grounding plate 168 disposed between the lid assembly 105 and the spacer 110, a substrate support 115, and a variable pressure system 120. The lid assembly 105 includes a lid plate 125 and a heat exchanger 130. In the embodiment shown, which can be combined with other embodiments described herein, the lid assembly 105 also includes a gas distributor, such as a showerhead 135.

The lid assembly 105 is coupled to a first processing gas source 140. The first processing gas source 140 contains precursor gases for forming films on a substrate 145 supported on the substrate support 115. As an example, the first processing gas source 140 includes precursor gases such as carbon containing gases, hydrogen containing gases, helium, among others. In a specific example, the carbon containing gas includes acetylene (C₂H₂). The first processing gas source 140 provides precursor gases to a plenum 190 disposed in the lid assembly 105. The lid assembly includes one or more channels for directing precursor gases from the first processing gas source 140 into the plenum 190. From the plenum, the precursor gases flow through the showerhead 135 and the grounding plate 168 into a processing volume 160.

The grounding plate 168 is fluidly coupled between the showerhead 135 and the spacer 110. In some embodiments, the grounding plate 168 has a plurality of passages therethrough for admitting precursor gases from the showerhead 135 into the processing volume 160. The precursor gases from the grounding plate 168 enter the processing volume 160 through the plurality of passages in the grounding plate 168 such that the precursor gases are uniformly distributed in the processing volume 160. In one embodiment, the plurality of passages in the grounding plate 168 may be radially distributed and gas flow to each of the plurality of passages may be separately controlled to further facilitate gas uniformity within the processing volume 160.

The grounding plate 168 may be made of any electrically conductive metallic material, such as aluminum, nickel, steel, and the like. In some embodiments, the grounding plate 168 has a thickness in a range from about 0.15 inch to about 1 inch. In certain embodiments, the grounding plate 168 has a thickness in a range from about 0.25 inch to about 0.6 inch. In some embodiments, the size and number of the plurality of passages may be modified as needed to adjust the distribution of precursor gases to the processing volume 160. In some embodiments, the size and number of the plurality of passages may be modified to modify a surface area of the grounding plate 168.

In some embodiments, which can be combined with other embodiments described herein, a second processing gas source 142 is fluidly coupled to the processing volume 160 via an inlet 144 disposed through the spacer 110. As an example, the second processing gas source 142 includes precursor gases such as carbon containing gases, hydrogen containing gases, helium, among others, for example C₂H₂. The flow of precursor gases in the processing volume 160 via the second processing gas source 142 modulates the flow of precursor gases flow through the showerhead 135 such that the precursor gases are uniformly distributed in the processing volume 160. In one example, a plurality of inlets 144 is radially distributed about the spacer 110. In such an example, gas flow to each of the inlets 144 is separately controlled to further facilitate gas uniformity within the processing volume 160.

The one or more first gas sources 140 are configured to introduce processing gases such as carbon-containing gases (such as hydrocarbon gases), hydrogen-containing gases, and/or helium. The present disclosure contemplates that other gases may be used. In one example, which can be combined with other examples, the processing gases include one or more of acetylene (C₂H₂) (which can be referred to as ethyne), propene (C₃H₆), methane (CH₄), butene (C₄H₈), 1,3-dimethyladamantane, bicyclo[2.2.1]hepta-2,5-diene (2,5-norbornadiene), adamantine (C₁₀H₁₆), norbornene (C₇H₁₀), any derivatives thereof, and/or any isomers thereof. The processing gases can include one or more dilution gases, one or more carrier gases, etchant gases, and/or one or more purge gases. In one example, which can be combined with other examples, the processing gases include one or more of helium, argon, xenon, neon, nitrogen (N₂), hydrogen (H₂), chlorine (Cl₂), carbon tetrafluoride (CF₄), and/or nitrogen trifluoride (NF₃).

In one embodiment, which can be combined with other embodiments, the one or more first gas sources 140 are configured to introduce acetylene (C₂H₂) and helium (He) into the processing volume 160.

As shown, the lid assembly 105 is also coupled to an optional remote plasma source 150. The remote plasma source 150 is coupled to a cleaning gas source 155 for providing cleaning gases to the processing volume 160 formed inside the spacer 110 between the lid assembly 105 and the substrate 145. In one example, cleaning gases are provided through a central conduit 191 formed axially through the lid assembly 105. In another example, cleaning gases are provided through the same channels which direct precursor gases. Example cleaning gases include oxygen-containing gases such as oxygen and/or ozone, as well fluorine containing gases such as NF₃, or combinations thereof.

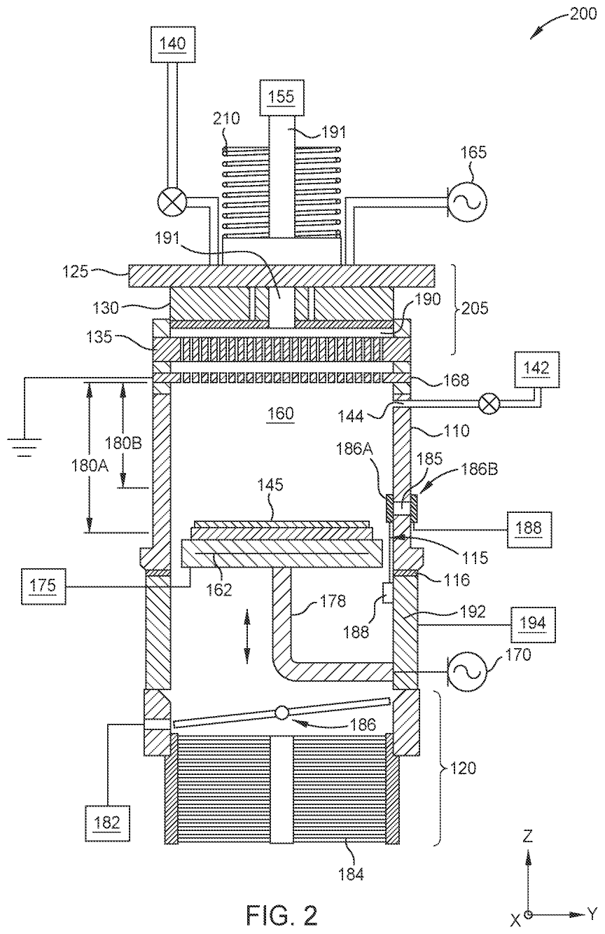

In addition to or as an alternative to the remote plasma source 150, the lid assembly 105 is also coupled to a first radio frequency (RF) power source 165. The first RF power source 165 facilitates maintenance or generation of plasma, such as a plasma generated from a cleaning gas. In one embodiment, the remote plasma source 150 is omitted, and the cleaning gas is ionized into a plasma in situ via the first RF power source 165. For example, in another embodiment, the plasma generated for cleaning may alternately be generated by an inductively coupled plasma source positioned on top of the process chamber 200 (or a peripheral coil), as shown in FIG. 2. In this configuration, a coil may be disposed on top of a lid assembly 205 and powered by the first RF power source 165 to generate a plasma from the cleaning gas provided from the cleaning gas source 155. In an embodiment, the lid assembly 205 including the showerhead 135 may include, be coated with, or be composed of an insulating or non-conductive material, such as a ceramic material to break and suppress eddy currents generated by the delivery of current to the coils of the inductively coupled plasma source. In such an embodiment, the lid assembly 205 including the showerhead 135 is therefore electrically insulated from the rest of the process chamber 200, such as the spacer 110. In other embodiments, where portions of the lid assembly 205 is formed from an electrically conductive material (e.g., metal), an additional insulating spacer or dielectric break (not shown), may alternatively be disposed between the lid assembly 205 and the spacer 110 or the chamber body 192 (if the spacer 110 not present) so as to electrically insulate the lid assembly 205 and the coils of the inductively coupled plasma source disposed thereon. In some embodiments, the lid assembly 205 may be coated with a ceramic coating, for protection from plasma species.

The substrate support 115 includes a RF electrode 162 coupled to a second or lower RF power source 170. The RF electrode 162 applies RF power to generate and tune the plasma. The first RF power source 165 is a high frequency RF power source (for example, about 13.56 MHz to about 120 MHZ) and the second RF power source 170 is a low frequency RF power source (for example, about 2 MHz to about 13.56 MHZ). It is to be noted that other frequencies are also contemplated. In some embodiments, the second RF power source 170 is a mixed frequency RF power source, providing both high frequency and low frequency power. Utilization of a dual frequency RF power source, particularly for the second RF power source 170, may improve film deposition. In one example, utilizing a second RF power source 170 provides dual frequency powers.

In the embodiment shown, the grounding plate 168 is grounded or coupled to an electrical ground. In some embodiments, the grounding plate 168 may be conductively coupled with the spacer 110. In some embodiments, the spacer 110 may not be used and the grounding plate 168 is disposed between the chamber body 192 and the lid assembly 105. The present disclosure contemplates that other components surrounding the processing volume 160 can also be grounded. In some embodiments, the grounding plate 168 and the spacer 110 coupled thereto may also both be grounded with the grounding plate 168 to increase a surface area of the ground defining the processing volume 160 and the generated plasma.

One or both of the first RF power source 165 and the second RF power source 170 are utilized in creating or maintaining a plasma in the processing volume 160. For example, the second RF power source 170 is utilized during a deposition process and the first RF power source 165 is utilized during a cleaning process (alone or in conjunction with the remote plasma source 150). In some deposition processes, the first RF power source 165 is used in conjunction with the second RF power source 170. During a deposition or etch process, one or both of the first RF power source 165 and the second RF power source 170 provide a power of about 100 Watts (W) to about 20,000 W in the processing volume 160 to facilitation ionization of a precursor gas. In one embodiment, which can be combined with other embodiments described herein, at least one of the first RF power source 165 and the second RF power source 170 are pulsed. In another embodiment, which can be combined with other embodiments described herein, the precursor gas includes helium and C₂H₂. In one embodiment, which can be combined with other embodiments described herein, C₂H₂ is provided at a flow rate of about 10 sccm to about 1,000 sccm and He is provided at a flow rate of about 50 sccm to about 10,000 sccm.

In some embodiments, during operation of the process chamber 100 or process chamber 200 to perform a deposition process, the second RF power source 170 may be configured to apply a DC bias to the RF electrode 162 to generate a plasma from processing gases flowed from the first processing gas source 140. In some embodiments, the plasma may be a capacitively coupled plasma (CCP) generated in the processing volume between the RF electrode 162 in the substrate support 115 and a grounded electrode. In some embodiments, the grounding plate 168 may be configured to operate as part of the grounded electrode for generating the CCP plasma in the processing volume 160. In some embodiments, the grounding plate 168 is conductively coupled with the spacer 110 or chamber body 192 (if the spacer 110 is not present) such that the spacer 110 or chamber body 192 also partially defining the processing volume are all utilized as part of the grounded electrode. In some embodiments, a surface area of the grounded electrode may therefore include a surface area of the grounding plate 168 facing the processing volume 160 and the surface area of the interior surface of the spacer 110 and/or chamber body 192 also facing and partially defining the processing volume 160. In some embodiments, the second RF power source 170 may continue to provide a DC bias to the powered electrode to maintain the plasma throughout the deposition process to form a film on the substrate 145.

The substrate support 115 is coupled to an actuator 175 (i.e., a lift actuator) that provides movement thereof in the Z direction. The substrate support 115 is also coupled to a facilities cable 178 that is flexible which allows vertical movement of the substrate support 115 while maintaining communication with the second RF power source 170 as well as other power and fluid connections. The spacer 110 is disposed on the chamber body 192. A height of the spacer 110 allows movement of the substrate support 115 vertically within the processing volume 160. The height of the spacer 110 is about 0.5 inches to about 20 inches. In one example, the substrate support 115 is movable from a first distance 180A to a second distance 180B relative to the lid assembly 105 (for example, relative to a lower surface of the showerhead 135). In one embodiment, the second distance 180B is about ⅔ of the first distance 180A. For example, the difference between the first distance 180A and the second distance is about 5 inches to about 6 inches. Thus, from the position shown in FIG. 1, the substrate support 115 is movable by about 5 inches to about 6 inches relative to a lower surface of the showerhead 135. In another example, the substrate support 115 is fixed at one of the first distance 180A and the second distance 180B.

During the deposition operation, the processing volume 160 and/or the substrate 145 is maintained at a deposition temperature and a deposition pressure. The deposition temperature is within a range of −50 degrees Celsius to 600 degrees Celsius. In one embodiment, which can be combined with other embodiments, the deposition temperature is within a range of 8 degrees Celsius to 12 degrees Celsius, such as 10 degrees Celsius. The deposition pressure is sub-atmospheric. The deposition pressure is within a range of 0.1 mTorr to 500 mTorr. The deposition pressure is within a range of 3 mTorr to 5 mTorr, such as 4 mTorr. During the deposition operation, the substrate support 115 is disposed at the second distance 180B, and the second distance is within a range of 3.5 inches to 4.5 inches, such as 4.0 inches.

The variable pressure system 120 includes a first pump 182 and a second pump 184. The first pump 182 is a roughing pump that is utilized during a cleaning process and/or substrate transfer process. A roughing pump is generally configured for moving higher volumetric flow rates and/or operating a relatively higher (though still sub-atmospheric) pressure. In one example, the first pump 182 maintains a pressure within the process chamber less than 50 mTorr during a cleaning process. In another example, the first pump 182 maintains a pressure within the process chamber of about 0.5 mTorr to about 10 Torr.

The second pump 184 is one a turbo pump and a cryogenic pump. The second pump 184 is utilized during a deposition process. The second pump 184 is generally configured to operate a relatively lower volumetric flow rate and/or pressure. For example, the second pump 184 is configured to maintain the processing volume 160 of the process chamber at a pressure of less than about 50 mTorr. In another example, the second pump 184 maintains a pressure within the process chamber of about 0.5 mTorr to about 10 mTorr.

In some embodiments, which can be combined with other embodiments described herein, both of the first pump 182 and the second pump 184 are utilized during a deposition process to maintain the processing volume 160 of the process chamber at a pressure of less than about 50 mTorr. In other embodiments, the first pump 182 and the second pump 184 maintain the processing volume 160 at a pressure of about 0.5 mTorr to about 10 mTorr. A valve 186 is utilized to control the conductance path to one or both of the first pump 182 and the second pump 184. The valve 186 also provides symmetrical pumping from the processing volume 160.

The process chamber 100 also includes a substrate transfer port 185. The substrate transfer port 185 is selectively sealed by an interior door 186A and an exterior door 186B. Each of the doors 186A and 186B are coupled to actuators 188 (i.e., a door actuator). The doors 186A and 186B facilitate vacuum sealing of the processing volume 160. The doors 186A and 186B also provide symmetrical RF application and/or plasma symmetry within the processing volume 160. Seals 116, such as O-rings, disposed at the interface of the spacer 110 and the chamber body 192 further seals the processing volume 160. A controller 194 coupled to the process chamber 100 is configured to control aspects of the process chamber 100 during processing.

In contrast to conventional plasma enhanced chemical vapor deposition (PECVD) processes, the grounding plate 168 can substantially increase a surface area of a grounded surface used to define the processing volume 160 of the process chamber 100. For example, in process chambers in which an inductively coupled plasma source is disposed on top of a ceramic lid assembly of a process chamber, the surface area of the grounded surface in such chambers may be limited to just the interior area of the spacer or chamber body due to the lid assembly being formed from an insulating and non-conductive material. In such process chambers, the addition of the ground plate 168 (e.g., the grounding plate 168 coupled with the spacer 110 or chamber boy 192, if no spacer 110 present) may therefore increase the surface area of the grounded surface defining the processing volume 160 by an additional surface area corresponding to about the cross-sectional area of the process chamber. For example, as compared to a process chamber with only grounded chamber walls defining the processing volume, the grounding plate 168 increases the surface area of the ground surface by about 2.5×.

FIG. 1 is a schematic side cross sectional view of an illustrative process chamber 100 suitable for conducting a deposition process, according to certain embodiments of the present disclosure.

FIG. 2 is a schematic side cross sectional view of an illustrative process chamber 200 suitable for conducting a deposition process, according to certain embodiments of the present disclosure. The process chamber 200 is similar to the process chamber 100 shown in FIG. 1. In the implementation shown in FIG. 2, the remote plasma source 150 is omitted, and a flat coil 210 is used (with or without the first RF power source 165) during the cleaning operation to excite a cleaning plasma (ICP) in the processing volume 160. The flat coil 210 is configured to inductively couple RF power into the process chamber 200 to generate cleaning plasma in-situ during the cleaning operation from cleaning gas provided from the cleaning gas source 155.

The following non-limiting examples are provided to further illustrate embodiments described herein. However, the examples are not intended to be all inclusive and are not intended to limit the scope of the embodiments described herein.

As discussed above, the increased surface area of the grounded surface provided by the additional grounding plate 168 inside the process chamber 100 assists in providing and maintaining a higher plasma potential during film deposition in the processing volume 160. Film deposited with the higher plasma potential in turn showed reduced compressive stress without much change to the density or modulus of the film. Although the examples discussed herein refer to forming amorphous carbon/DLC films, the increased surface area of the ground by the grounding plate 168 may similarly benefit and facilitate reducing the compressive stress of other films formed using high RF input power (e.g., over 550 W), for example, silicon oxide and silicon nitride films.

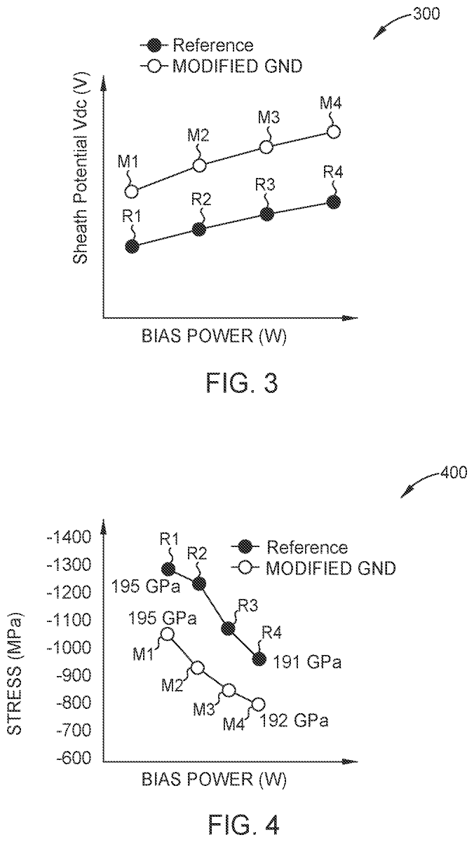

FIG. 3 depicts a graphical representation 300 of four comparative samples of the sheath voltage (V_{DC}) during the deposition of DLC films in process chambers without the modified ground surface area (e.g., R1, R2, R3, and R4) as a reference, and four samples of the Voc during the deposition of the same DLC films using process chambers with the modified ground surface area increased by the addition of the grounding plate (e.g., M1, M2, M3, and M4). The samples are arranged according to increasing applied bias power (e.g., from 800 W to 2400 W), with R1 and M1 indicating the V_{DC} for films formed with the lowest applied bias power, and R4 and R4 indicating the V_{DC} for films formed with the highest applied bias power. Each of the DLC films were deposited using C₂H₂ and He gases flowed at 150 sccm each to form CCP plasma at 13 MHz. The processing pressure in each was about 4 mTorr. The processing temperature in each was about 10 degrees Celsius. Each of the comparative samples showed an increase in the sheath voltage when the process chamber with the modified ground surface area was used regardless of the bias power applied. In some embodiments, in process chambers in which the grounded surface area is about 2.5× greater, the sheath voltage during deposition was about 30% greater than the sheath voltage of films formed in the reference process chambers. Regardless of the ion transit time, the higher sheath potential indicates the ion energy of the deposition species was generally increased in the process chambers with the modified ground surface area.

After the DLC films discussed above in FIG. 3 were formed, each of the films were tested for stress properties. FIG. 4 depicts a graphical representation of the corresponding as deposited compressive stress value of the DLC films in the modified and reference process chambers. The values of the compressive stress may be considered as negative values because the stress is compressive, but the absolute values for the compressive stress are described as positive values herein. Each of the comparative samples showed a decrease in absolute stress values (e.g., decrease in stress values). In some embodiments, the absolute stress values formed in the modified process chamber were about 200 MPa less than the films formed in the reference process chamber. All of the samples formed in the modified process chambers substantially maintained similar modulus values relative to the samples formed in the reference chambers. As shown in FIG. 4, both of the samples formed using 800 W bias power had a modulus of about 195 GPA, and both of the samples formed using 2400 W bias power had a modulus of about 192 GPA, only 1 GPA greater than the film formed in the reference process chamber.

Benefits of the present disclosure include reducing compressive stress of deposited films while maintaining modulus of the deposited films, reduced film wiggling, reduced deformation of films and substrates, enhanced etching performance for hardmasks, and enhanced device performance.

As an example, it is believed that the present disclosure (such as by increasing the grounded surface area in the process chamber by about 2.5×) facilitates about a 20% reduction in film stress while maintaining the modulus within a predetermined range (such as a range of 190 GPa or higher). As another example, it is believed that the increased ground surface area provides for increased ion energy that facilitates film deposition and enhanced ion bombardment to reduce compressive stress of the film while maintaining a modulus (e.g., a Young's modulus) of the deposited film.

It is contemplated that one or more aspects disclosed herein may be combined. As an example, one or more aspects, features, components, and/or properties of the process chamber 100 and process chamber 200 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

What is claimed is:

1. A process chamber, comprising
a chamber body having a processing volume;
a substrate support comprising a powered electrode, the substrate support disposed in the chamber body and partially defining the processing volume;
a gas distributor disposed above the chamber body and facing the substrate support, wherein the gas distributor is electrically insulated from the chamber body;
a RF power source configured to apply a RF power to the powered electrode to generate and maintain a plasma in the processing volume between the powered electrode and a grounded electrode; and
a grounding plate disposed between the chamber body and the gas distributor and partially defining the processing volume, wherein the grounding plate is coupled to an electrical ground, comprises a plurality of passages extending therethrough, and is configured to operate as at least part of the grounded electrode for generating and maintaining the plasma in the processing volume.

2. The process chamber of claim 1, wherein a grounded surface area of the grounded electrode comprises a surface area of the grounding plate and an interior surface area of the chamber body at least partially defining the processing volume.

3. The process chamber of claim 2, wherein the grounding plate increases the grounded surface area of the grounded electrode by about 2.5×.

4. The process chamber of claim 1, wherein the plasma generated by the RF power source in the processing volume is a capacitively coupled plasma.

5. The process chamber of claim 1, wherein the processing volume is defined by the grounding plate, the substrate support, and the chamber body.

6. The process chamber of claim 1, further comprising a spacer disposed between the chamber body and the grounding plate and partially defining the processing volume, and wherein a grounded surface area of the grounded electrode comprises a surface area of the grounding plate and an interior surface area of the spacer.

7. The process chamber of claim 1, wherein the grounding plate is conductively coupled with the chamber body.

8. The process chamber of claim 1, wherein the plurality of passages is configured to fluidly connect the gas distributor and the processing volume.

9. The process chamber of claim 1, further comprising an inductively coupled plasma source disposed on a lid assembly coupled to and above the chamber body, the lid assembly comprising the gas distributor and a ceramic material to provide a dielectric break between the inductively coupled plasma source and the chamber body.

10. The process chamber of claim 1, wherein when the RF power applied is greater than about 550 W and the grounding plate coupled with the chamber body is configured as the grounded electrode to generate a capacitively coupled plasma in the processing volume, the grounding plate increases a sheath voltage of the powered electrode by about 30%.

11. The process chamber of claim 1, wherein when the grounding plate is used as the grounded electrode to generate a capacitively coupled plasma in the processing volume, the grounding plate provides enhanced ion bombardment of a substrate disposed on the substrate support.

12. A process chamber, comprising
a lid assembly;
an inductively coupled plasma source disposed on the lid assembly;
a chamber body coupled to the lid assembly, wherein the lid assembly and the chamber body defines a chamber volume, and the lid assembly comprises a non-conductive material for providing a dielectric break between the inductively coupled plasma source and the chamber body;
a substrate support comprising a powered electrode, the substrate support disposed in the chamber volume and partially defining a processing volume in the chamber volume; and
a grounding plate coupled to an electrical ground and disposed between the lid assembly and the chamber body, wherein the grounding plate is configured to operate as part of a grounded electrode for generating a plasma in the processing volume between the powered electrode and the grounded electrode, and a grounded surface area of the grounded electrode comprises a surface area of the grounding plate and an interior surface area of the chamber body.

13. The process chamber of claim 12, further comprising a first RF power source for powering the inductively coupled plasma source.

14. The process chamber of claim 13, further comprising a second RF power source for providing a RF power to the powered electrode for generating and maintaining the plasma in the processing volume.

15. The process chamber of claim 12, wherein the lid assembly comprises a gas distributor for providing a processing gas from a gas source, and the grounding plate comprises a plurality of passages to fluidly connect the gas distributor and the processing volume.

16. The process chamber of claim 12, further comprising a spacer disposed between the grounding plate and the substrate support, and wherein the processing volume is defined by the grounding plate, the spacer, and the substrate support.

17. A process chamber, comprising:
a lid assembly;
an inductively coupled plasma source disposed on the lid assembly;
a chamber body coupled to the lid assembly, wherein the lid assembly and the chamber body defines a chamber volume and the lid assembly is electrically insulated from the chamber body;
a substrate support comprising a powered electrode, the substrate support disposed in the chamber volume and partially defining a processing volume in the chamber volume; and
a grounding plate coupled to an electrical ground and disposed between the lid assembly and the chamber body, wherein the grounding plate comprises:
a plate body configured to be coupled with the chamber body and partially defining the processing volume;
a plurality of passages extending through the plate body; and
a grounding surface facing the processing volume and the substrate support when the plate body is coupled to the chamber body, wherein:
the plate body is configured to operate as part of a grounded electrode for generating a capacitvely coupled plasma in the processing volume between the powered electrode and the grounded electrode; and
a grounded surface area of the grounded electrode comprises a surface area of the plate body and an interior surface area of the chamber body at least partially defining the processing volume when the plate body is coupled to the chamber body.

18. The process chamber of claim 17, wherein a thickness of the plate body is between about 0.2 inches and about 1 inch.

19. The process chamber of claim 17, wherein the plate body comprises an electrically conductive metallic material.

20. The process chamber of claim 17, wherein when the plate body is coupled to the chamber body of the process chamber, the plurality of passages is configured to fluidly connect a gas distributor of the process chamber to the processing volume.
